(19) United States
(12) Patent Application Publication
(10) Pub. No.: US 2025/0293206 A1
(43) Pub. Date: Sep. 18, 2025

(54) SEMICONDUCTOR DEVICE AND METHOD OF MANUFACTURING SEMICONDUCTOR DEVICE

(71) Applicant: Samsung Electronics Co., Ltd., Suwon-si (KR)

(72) Inventors: Junho Yoon, Anyang-si (KR); Junyun Kweon, Suwon-si (KR); Taeduk Nam, Suwon-si (KR); Haemin Park, Suwon-si (KR)

(21) Appl. No.: 18/894,091

(22) Filed: Sep. 24, 2024

(30) Foreign Application Priority Data
Mar. 12, 2024 (KR) 10-2024-0034329

(51) Int. Cl. H01L 25/065; H10B 43/27; H10B 80/00

(52) U.S. Cl. CPC H01L 25/0652; H10B 43/27; H10B 80/00; H01L 2225/06506

(57) ABSTRACT

A semiconductor package includes a semiconductor chip including a substrate, an interconnection structure on a front surface of the substrate, and a pad layer on a front surface of the interconnection structure. A first side surface of the semiconductor chip from a point on a side surface of the substrate to an edge of a front surface of the semiconductor chip is oblique to, or more curved than, the front surface of the semiconductor chip, and is oblique to, or more curved than, a second side surface of the semiconductor chip from the point to an edge of a back surface of the semiconductor chip.

### CROSS-REFERENCE TO RELATED APPLICATION(S)

This application claims priority under 35 USC 119(a) of Korean Patent Application No. 10-2024-0034329 filed on Mar. 12, 2024 in the Korean Intellectual Property Office, the entire disclosure of which is incorporated herein by reference.

### BACKGROUND

Aspects of the present inventive concept relate to a semiconductor device and a method of manufacturing a semiconductor device.

In accordance with the trend for miniaturization and higher performance of semiconductor devices such as semiconductor packages, at least one semiconductor chip included in the semiconductor package is also reduced in size and has higher performance. A plurality of semiconductor chips may be formed by dividing a plurality of regions of a wafer from each other, and miniaturization and increased performance of at least one semiconductor chip are increasing the difficulty of preventing defects (for example, cracking, kinking, peeling, and the like) in semiconductor chips caused by wafer division. The higher the difficulty in preventing defects, the more difficult it may be to increase productivity (for example, yield, costs, time, or the like) of wafer division.

### SUMMARY

Example embodiments provide a semiconductor device and a method of manufacturing a semiconductor device, in which defects (for example, cracks, kinking, peeling, and the like) in semiconductor chips caused by wafer division may be effectively prevented and productivity (for example, yield, cost, time, and the like) of wafer division may be efficiently increased.

According to example embodiments, a semiconductor device includes a semiconductor chip including a substrate, an interconnection structure on a front surface of the substrate, and a pad layer on a front surface of the interconnection structure. As viewed from a cross-section, a first side surface of the semiconductor chip from a point on a side surface of the substrate to an edge of a front surface of the semiconductor chip is oblique to, or more curved than the front surface of the semiconductor chip, and is oblique to, or more curved than a second side surface of the semiconductor chip from the point to an edge of a back surface of the semiconductor chip.

According to example embodiments, a semiconductor package includes a semiconductor chip including a substrate, an interconnection structure disposed on a front surface of the substrate, and a pad layer disposed on a front surface of the interconnection structure. As viewed from a cross-section, a first side surface of the semiconductor chip from a point on a side surface of the substrate to an edge of a front surface of the semiconductor chip has a heat affected zone. The point is a bottom of the heat affected zone.

According to example embodiments, a method of manufacturing a semiconductor package includes forming a groove in a front surface of a wafer using a laser; and separating a plurality of portions of the wafer connected to each other with the groove therebetween by applying tension to the wafer so that the plurality of portions are spaced apart from each other.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1A and 1B are a perspective view and a cross-sectional view illustrating wafer division in a semiconductor device and a method of manufacturing a semiconductor device according to example embodiments;

FIGS. 2A to 2E are cross-sectional views illustrating a method of manufacturing a semiconductor device according to example embodiments;

FIGS. 3A to 3D are cross-sectional views illustrating a method of manufacturing a semiconductor device according to example embodiments;

FIGS. 4A to 4C are cross-sectional views illustrating a semiconductor device according to example embodiments;

FIGS. 5A to 5C are cross-sectional views illustrating a structure in which a memory chip is disposed on the front surface of a semiconductor chip of a semiconductor device according to example embodiments;

FIGS. 6A to 6C are cross-sectional views illustrating a method of manufacturing a semiconductor device according to example embodiments;

FIGS. 7A and 7B are cross-sectional views illustrating a method of manufacturing a semiconductor device according to example embodiments;

FIG. 7C is a cross-sectional view illustrating a semiconductor device according to example embodiments;

FIGS. 8A to 8B are cross-sectional views illustrating a method of manufacturing a semiconductor device according to example embodiments;

FIG. 8C is a cross-sectional view illustrating a semiconductor device according to example embodiments;

FIGS. 9A to 9C are cross-sectional views illustrating various shapes of grooves in a semiconductor device and a method of manufacturing a semiconductor device according to example embodiments;

FIG. 10A is a cross-sectional view illustrating a structure in which a plurality of semiconductor chips of a semiconductor package according to example embodiments are connected to each other through direct bonding; and

FIG. 10B is a cross-sectional view illustrating a structure in which a semiconductor chip of a semiconductor package according to example embodiments is electrically connected to a redistribution line.

### DETAILED DESCRIPTION

The detailed description of the present inventive concept described below refers to the accompanying drawings, which illustrate by way of example specific embodiments in which the present inventive concept may be practiced. These embodiments are described in sufficient detail to enable those skilled in the art to practice the present inventive concept. It should be understood that the various embodiments of the present inventive concept are different from one another but are not necessarily mutually exclusive. For example, specific shapes, structures and characteristics described herein with respect to an example embodiment may be implemented in other embodiments without departing from the spirit and scope of the present inventive concept. Additionally, it should be understood that the location or arrangement of individual elements within each disclosed embodiment may be changed without departing from the spirit and scope of the present inventive concept. Accordingly, the detailed description set forth below is not intended to be taken in a limiting sense, and the scope of the present invention is limited only by the appended claims, together with all equivalents to what those claims assert. Similar reference numbers in the drawings refer to identical or similar functions across various aspects.

Hereinafter, example embodiments of the present inventive concept will be described in detail with reference to the attached drawings to enable those skilled in the art to easily practice the present invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Items described in the singular herein may be provided in plural, as can be seen, for example, in the drawings. Thus, the description of a single item that is provided in plural should be understood to be applicable to the remaining plurality of items unless context indicates otherwise.

Terms such as “same,” “equal,” “planar,” “coplanar,” “flat,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

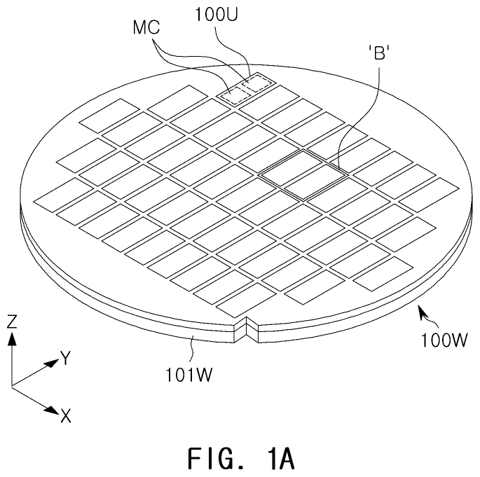

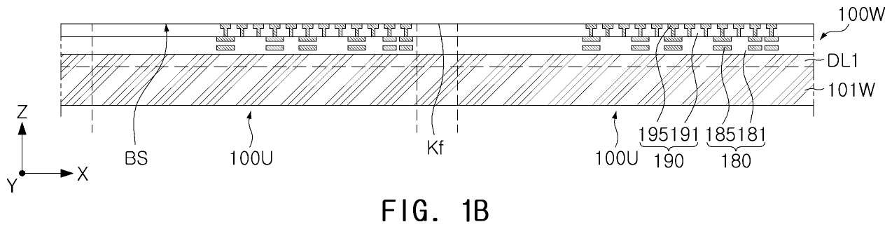

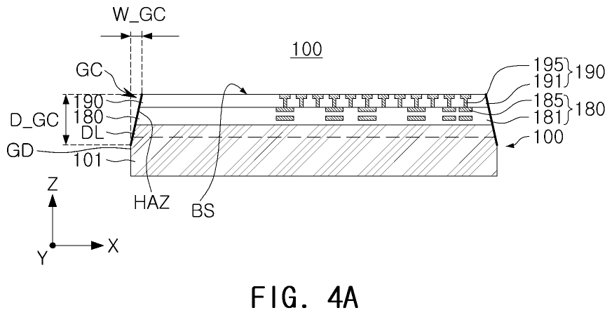

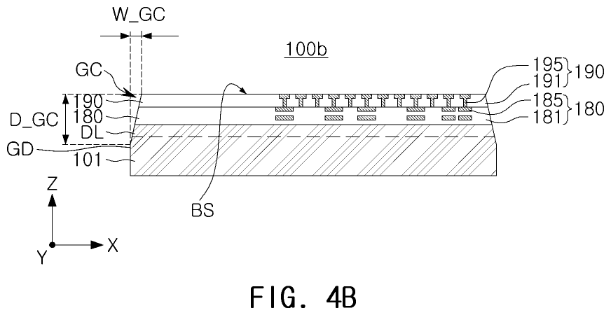

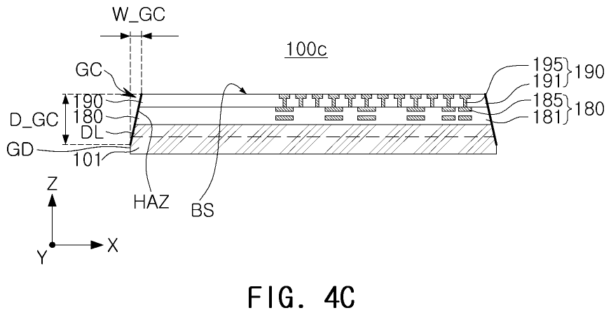

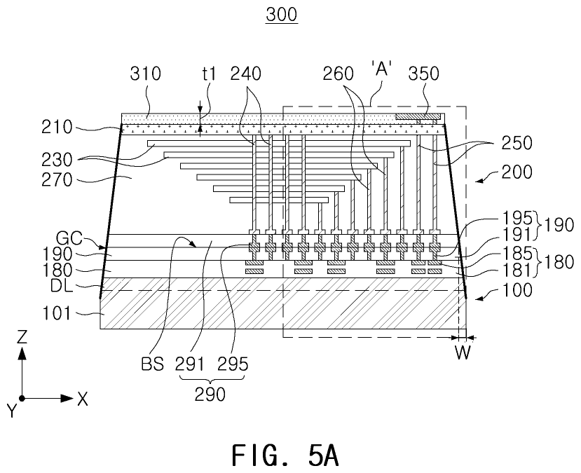

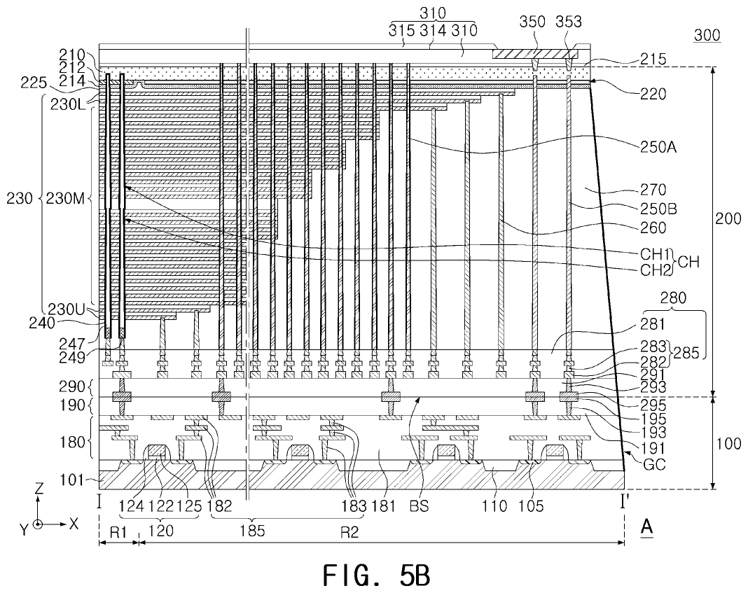

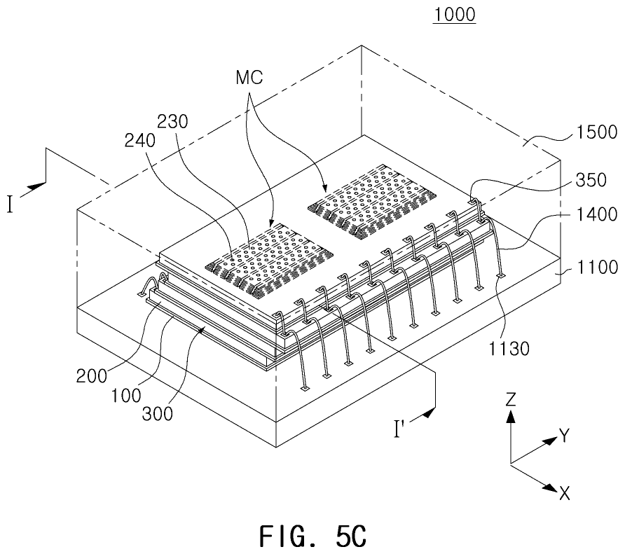

FIG. 1B illustrates an X-Z cross-section of a wafer 100W obtained by cutting a specific area (B) of the wafer 100W in FIG. 1A along the X-Z plane. The method of manufacturing a semiconductor device such as a semiconductor package according to example embodiments may manufacture a plurality of semiconductor chips (100 in FIG. 4A) by dividing the plurality of portions 100U of the wafer 100W from each other. Referring to FIGS. 1A and 5C, each of the plurality of portions 100U may include a plurality of memory cell arrays MC, and the plurality of memory cell arrays MC may be the upper structure of a semiconductor chip (100 in FIG. 5C). A semiconductor device, as described herein, may refer to a semiconductor chip formed on a die from a wafer and separated from the wafer, may refer to two more semiconductor chips stacked on each other, which are part of or which form a semiconductor package, or may refer to a semiconductor package or package-on-package device.

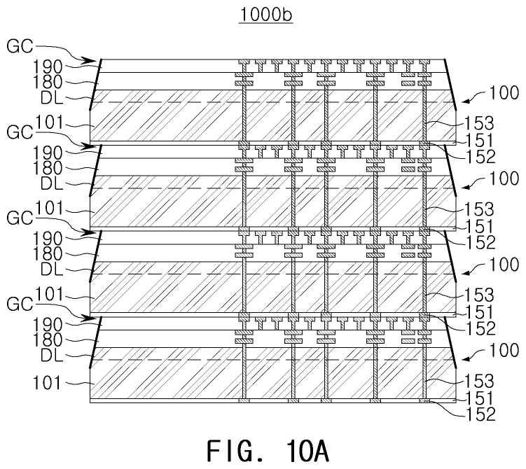

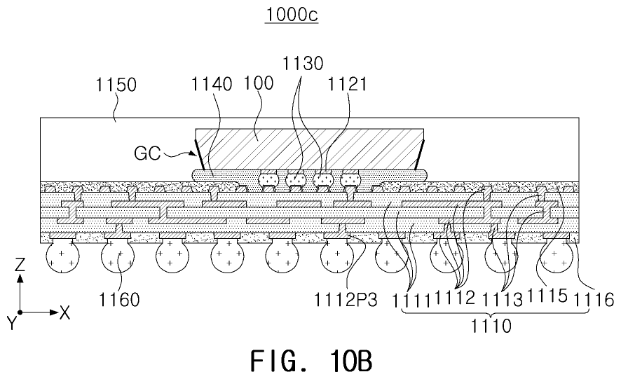

Referring to FIGS. 1A and 1B, the wafer 100W may include a substrate 101W, an interconnection structure 180, and a pad layer 190, and the substrate 101W may include a device layer DL1. The interconnection structure 180 and the pad layer 190 may be formed using a photolithography method. The front surface BS of the wafer 100W may provide an arrangement space for at least one of a memory chip (200 in FIG. 5A), a plurality of semiconductor chips (100 in FIG. 10A), and a redistribution structure (1110 in FIG. 10B) that may be disposed on the front surface BS may be flat.

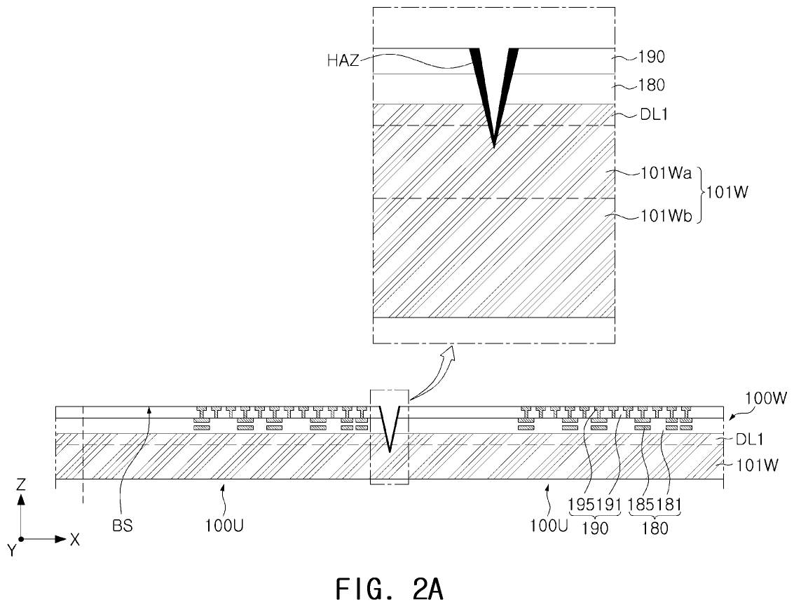

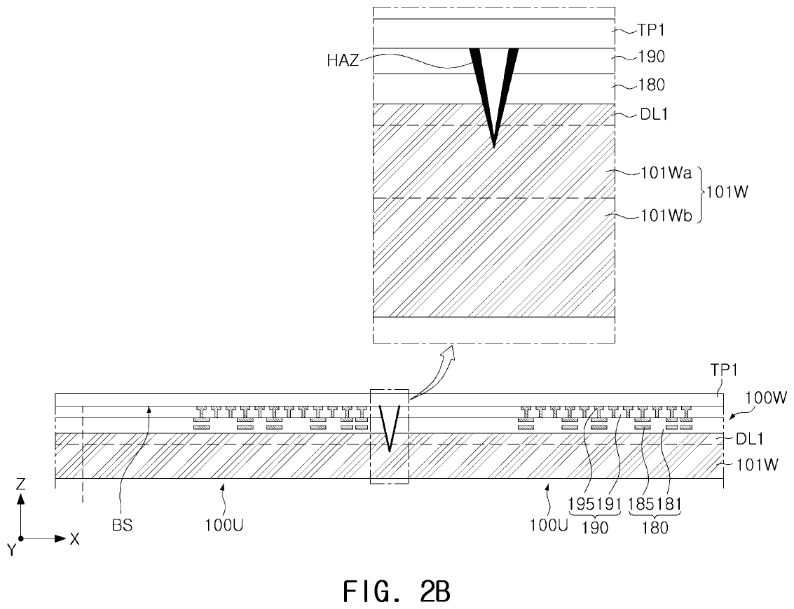

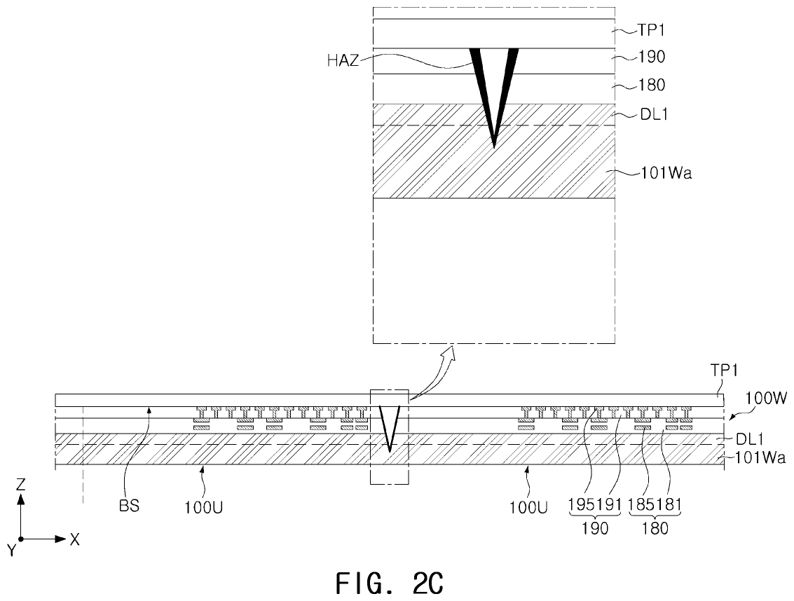

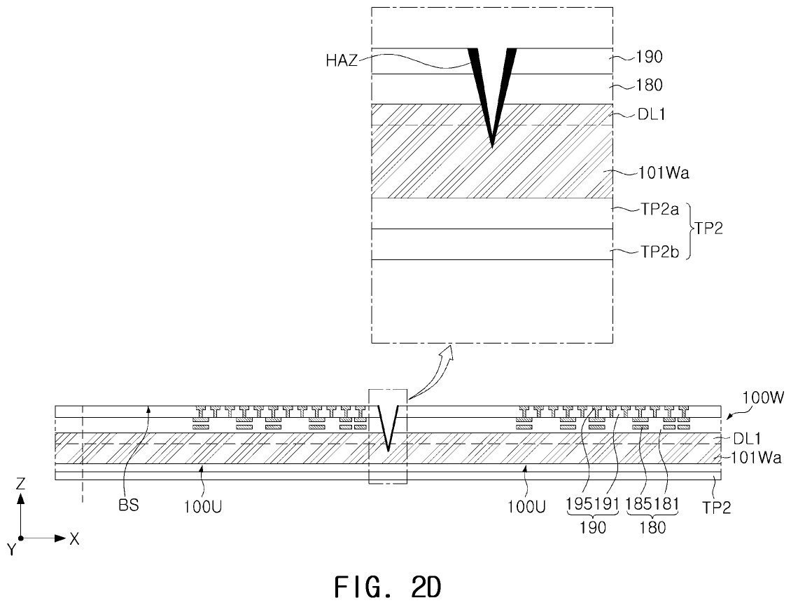

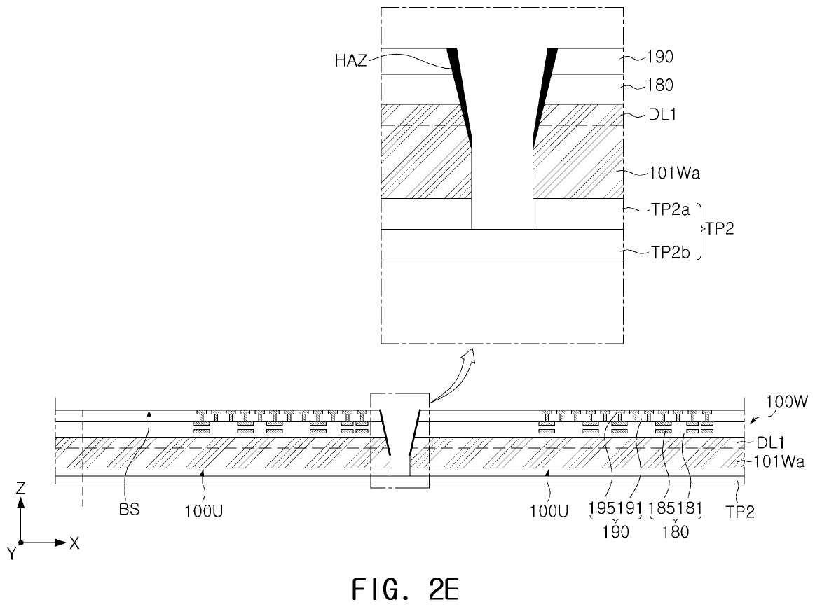

FIGS. 2A to 2E sequentially illustrate the process of dividing a plurality of portions 100U along the scribe lane area Kf of the wafer 100W of FIG. 1B, and at least one of FIGS. 2A to 2E may be changed or omitted depending on the design.

Referring to FIG. 2A, a method of manufacturing a semiconductor package according to example embodiments may include forming a groove in the front surface BS of the wafer 100W using a laser. The location of the groove may correspond to the scribe lane area Kf in FIG. 1B, and the groove may have a heat affected zone HAZ.

For example, a layer of non-photosensitive material such as Protection Layer Coating (PLC) may be temporarily placed on the front surface BS, and the PLC layer may have a through hole to expose an area corresponding to the scribe lane area Kf of FIG. 1B. The laser irradiator may penetrate the through hole and focus the laser on a local point on the front surface BS of the wafer 100W. For example, the laser irradiator may be a femtosecond laser irradiator or a nanosecond laser irradiator.

Accordingly, the laser irradiator may increase the laser energy at the local point to the ablation threshold power or more and may form a groove. As the amount of time elapses during which the laser energy at the local point equals or is greater than the ablation threshold power, the groove may be formed gradually deeper. The heat affected zone HAZ of the groove may continue continuously to the back-end of the groove (e.g., a bottommost point of the groove).

The heat affected zone HAZ of the groove may be formed by melting/vaporization of the insulating material and/or metal or semiconductor material included in the substrate 101W, the interconnection structure 180, and the pad layer 190, and may also be formed by melting/vaporization followed by melting/recrystallization. Therefore, the Heat Affected Zone HAZ may be in the form of a mixture of the semiconductor material and insulating material (for example, at least one of Si, SiO₂, SiN, SiCN, and TEOS) and the metal material (for example, at least one of Cu, Al, copper alloy, and aluminum alloy). Alternatively, the heat affected zone HAZ of the groove may have a form in which the insulating material and/or the metallic material is burned by laser energy. Alternatively, the heat affected zone HAZ of the groove may have a rougher form due to the laser energy. The heat affected zone HAZ refers to a portion of the wafer that has been affected (e.g., deformed, burnt, melted, etc.) by heat (e.g., from a laser), and may therefore be a burnt zone, a melted zone, or a heat-deformed zone.

Depending on the design of the lens of the laser irradiator (for example, lens position, refractive index), the shape of the groove formed by the laser irradiator may be determined. For example, the groove may be V-shaped in cross-section, and the back-end of the heat-affected zone HAZ may be a vertex in cross-section. The depth of the groove may be deeper than the total thickness of the interconnection structure 180 and the pad layer 190. The depth of the groove may be deeper than the total thickness of the interconnection structure 180, pad layer 190, and device layer DL1. The groove and heat affected zone HAZ may continue continuously from a point in or on the substrate 101W to the front (upper) surface of the pad layer 190.

As the time and/or number of times the laser irradiator irradiates the laser increases, the grooves may be formed deeper, but the heat affected zone HAZ may also be larger. The smaller the heat affected zone HAZ, the stronger the strength of each of the plurality of portions 100U may be. For example, the strength of a semiconductor chip (e.g., compressive strength) having a heat-affected zone HAZ formed when a laser irradiator irradiates the laser once or twice may be 557 MPa or more, and the strength of a semiconductor chip having a heat-affected zone formed when a laser irradiator irradiates the laser five or more times may be 355 MPa or less. The stronger the semiconductor chip, the lower the probability of defects (for example, cracks, kinking, peeling, and the like) occurring in the semiconductor chip.

In the method of manufacturing a semiconductor package according to example embodiments, the groove may be formed so that the depth of the groove and the heat affected zone HAZ is shorter than the total thickness of the semiconductor chip (100 in FIG. 4A). Since part of the thickness of the substrate 101W may be divided without irradiating the laser, the size of the heat affected zone HAZ may be reduced, and the strength of the semiconductor chip (100 in FIG. 4A) may be improved, and defects (for example, cracks, kinking, peeling, and the like) of the semiconductor chip may be reduced. Alternatively, the method of manufacturing a semiconductor package according to example embodiments may reduce the time and/or number of laser irradiation, thereby efficiently increasing the productivity (for example, yield, cost, time, and the like) of wafer division.

Referring to FIGS. 2B and 2C, a method of manufacturing a semiconductor package according to example embodiments may include reducing the thickness of the wafer 100W. Referring to FIG. 2B, the operation of reducing the thickness may include adhering the protective tape TP1 to the front surface BS of the wafer 100W. For example, the protective tape TP1 may include an adhesive layer such as a UV curable film and may include a carrier substrate.

Referring to FIG. 2C, the operation of reducing the thickness may include grinding the backside of the wafer 100W. Accordingly, a portion of the substrate 101W (101Wb in FIG. 2B) may be removed, and only the thinned substrate 101Wa may remain. The thickness of the substrate 101Wa may be longer than the depth of the groove and heat affected zone HAZ (e.g., the substrate 101 Wa may extend vertically below a bottom of the groove and heat affected zone HAZ). For example, grinding may be a grinding process, which may include a chemical mechanical polishing (CMP) process and/or an etch-back process. Afterwards, the protective tape TP1 may be removed.

Referring to FIGS. 2D and 2E, a method of manufacturing a semiconductor package according to example embodiments may include separating a plurality of portions 100U by applying tension to the wafer 100W so that a plurality of portions 100U of the wafer 100W connected to each other across a groove and a heat affected zone HAZ are spaced apart from each other. Referring to FIG. 2D, the separating step may include adhering a tension tape TP2 to the back surface of the wafer 100W. For example, the tensile tape TP2 may be Die Attach Film (DAF) and may include an adhesive layer TP2a such as a UV curable film, and may include a base layer TP2b containing a material that is advantageous in lengthening by tensile force.

Referring to FIG. 2E, the separating step may include separating the plurality of portions 100U by applying a tensile force to the tensile tape TP2. For example, both ends of a device that applies tension may be connected to both ends of the base layer TP2b, and the device may pull the base layer TP2b. For example, the equipment may include a plurality of rollers provided at both ends and on which the base layer TP2b is mounted or connected, and by rotating the plurality of rollers in opposite directions, tension may be applied to the base layer TP2b by the plurality of rollers.

By separating the plurality of portions 100U, the substrate 101Wa and the adhesive layer TP2a may be separated into a plurality of portions. Depending on the formation of the groove and the heat affected zone HAZ, the strength of the portion of the substrate 101Wa that overlaps the heat affected zone HAZ in the Z-direction may be weaker than the strength of other portions of the substrate 101Wa. Accordingly, the plurality of portions 100U may be stably separated by applying a tensile force to the tensile tape TP2. If the shape of the groove and heat affected zone HAZ is V-shaped in cross section, separation of the plurality of portions 100U may start from the vertex of the V shape and continue to the back (lower surface) of the plurality of portions 100U.

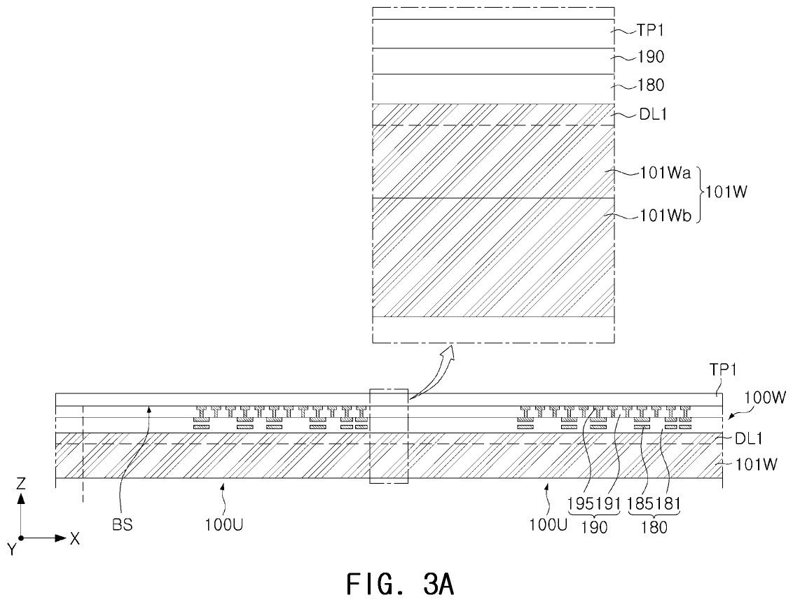

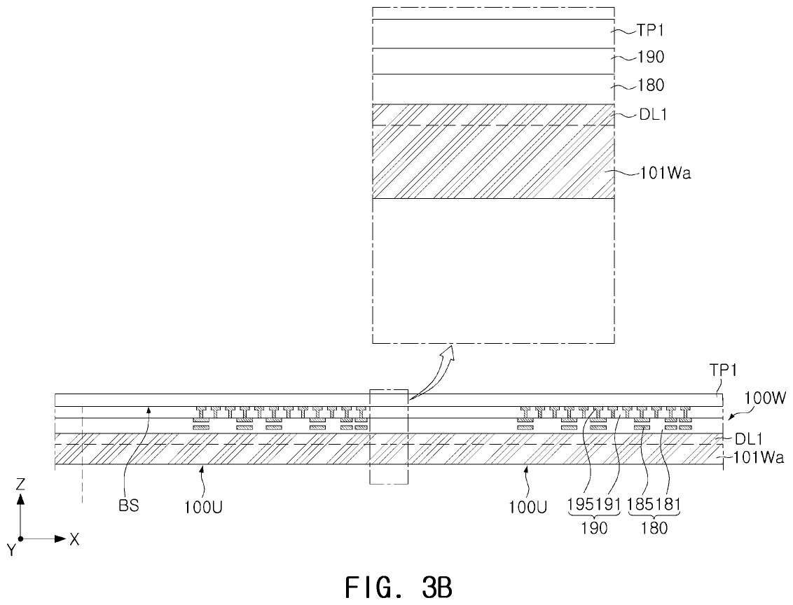

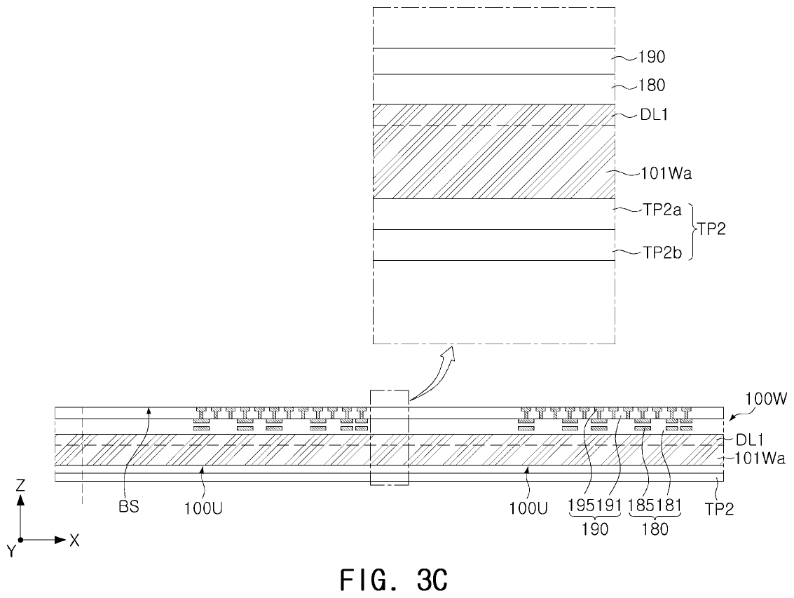

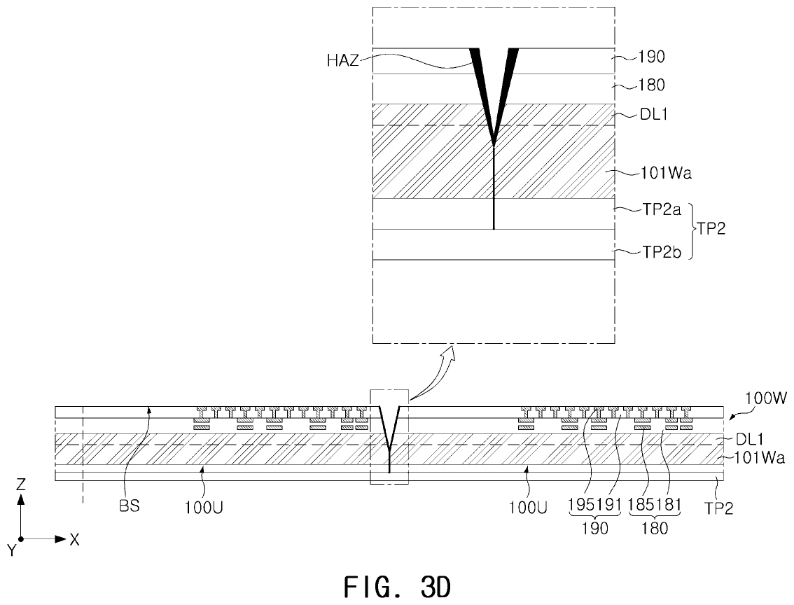

FIGS. 3A to 3D illustrate that the order of forming a groove and reducing the thickness of the wafer 100W in the method of manufacturing a semiconductor package of FIGS. 2A to 2E is reversed. Referring to FIGS. 3A to 3D, the operation of forming a groove in the method of manufacturing a semiconductor package according to example embodiments may be performed after the operation of reducing the thickness of the wafer 100W.

Referring to FIG. 3A, the protective tape TP1 may be disposed on the front surface BS of the wafer 100W. Referring to FIGS. 3A and 3B, a portion 101Wb of the substrate 101W may be removed, and only a thinner substrate 101Wa may remain. Referring to FIG. 3C, the tension tape TP2 may be disposed on the backside (lower surface) of the wafer 100W. Referring to FIG. 3D, a groove and a heat affected zone HAZ may be formed along the scribe lane area (Kf in FIG. 1B) on the front surface BS of the wafer 100W. Thereafter, the base layer TP2b of the tensile tape TP2 may apply a tensile force to separate the plurality of portions 100U.

FIGS. 4A to 4C are cross-sectional views illustrating portions of a semiconductor device such as a semiconductor package according to example embodiments, and may be manufactured by the above-described method of manufacturing a semiconductor package, but are not limited thereto.

Referring to FIGS. 4A to 4C, the semiconductor chips 100, 100b, and 100c of the semiconductor package according to example embodiments may include a substrate 101, an interconnection structure 180 disposed on the front (upper surface) of the substrate 101, and a pad layer 190 disposed on the front (upper surface) of the interconnection structure 180.

Referring to FIG. 4A, the first side surface GC of the semiconductor chip 100 from a point on the side surface of the substrate 101 to the edge of the front surface BS of the semiconductor chip 100 may be inclined with respect to the second side surface GD of the semiconductor chip 100 from a point on the side surface of the substrate 101 to the edge of the back surface of the semiconductor chip 100 or may be more curved than the second side surface. The first side surface GC may be oblique to the front surface BS (e.g., may form an angle with the front surface BS greater than 90°)or may be more curved than the front surface BS, and the second side surface may be perpendicular to the front surface BS. The first side surface GC of the semiconductor chip 100 may have a heat affected zone HAZ, and a point on the side surface of the substrate 101 may be the back-end (e.g., bottommost point) of the heat affected zone HAZ. For example, the heat affected zone HAZ may extend along the side surface of the semiconductor chip 100 to a bottommost point, which may correspond to a point on the side surface of the semiconductor chip 100. Above that point, the side surface of the semiconductor chip 100 may have a horizontal slope or may be curved, and below that point, the side surface of the semiconductor chip 100 may have a vertical slope perpendicular to the front surface BS of the semiconductor chip 100.

For example, the first side surface GC may be formed by forming the groove illustrated in FIGS. 2A and 3D, and may thus be oblique with respect to the anteroposterior direction (for example, Z-direction) and the lateral direction (for example, X-direction). For example, the second side surface may be formed by separating the plurality of portions 100U illustrated in FIG. 2E, and may be parallel to the front-back direction (for example, Z-direction), and may be perpendicular to the lateral direction (for example, X-direction) and may not have a heat affected zone HAZ. The strength of the second side surface may be stronger than that of the first side surface GC. In the semiconductor chip 100 of the semiconductor package according to example embodiments, the decrease in strength due to the formation of the first side surface GC may be reduced, and thus, defects (for example, cracks, kinking, peeling, and the like) of the semiconductor chip 100 may be reduced. Since the process for forming the first side surface GC may be reduced, the productivity (for example, yield, cost, time, and the like) of wafer division may be efficiently increased.

For example, in the lateral direction (for example, X-direction) of the semiconductor chip 100, the width W_GC of the first side surface GC of the semiconductor chip 100 may be equal to a maximum width of the heat affected zone HAZ, and the width of the heat affected zone HAZ may increase from 0 μm to a maximum width (for example, a maximum width greater than 3 μm but less than 100 μm) in a direction from a point on the side surface of the substrate 101 to the edge of the front surface BS of the semiconductor chip 100. The width W_GC may be a width in a first horizontal direction (e.g., X direction) when viewed from a second horizontal direction (e.g., a Y direction) perpendicular to the first direction, between a vertical line extended from the second side surface GD and an edge between the first side surface GC and the front surface BS. Thus, the second side surface GD may have a maximum height component (D-GC) in a vertical direction and a maximum width component W_GC in a horizontal direction. The width component may refer to the width in the first horizontal direction (e.g., X direction) when viewed from the second horizontal direction (e.g., a Y direction) perpendicular to the first direction, between a vertical line extended from the second side surface GD and an edge between the first side surface GC and the front surface BS. The height component may refer to a height in a vertical direction (e.g., Z direction) when viewed from a second horizontal direction (e.g., a Y direction) perpendicular to the first direction (e.g. X direction) and vertical direction, between a horizontal line extended from the front surface BS and the point on the side surface. The heat affected zone HAZ may continuously extend from a point on the side surface of the substrate 101 to the edge of the front surface BS of the semiconductor chip 100. The roughness of the first side surface GC of the semiconductor chip 100 may be rougher than the roughness of the second side surface of the semiconductor chip 100.

For example, the side surface of the substrate 101 may have an angular shape at one point of the side surface of the substrate 101. The angle of the angled shape may vary depending on the location of the back-end of the heat affected zone HAZ. The first side surface GC of the semiconductor chip 100 has a substantially flat shape from a point on the side surface of the substrate 101 to the edge of the front surface BS of the semiconductor chip 100, and the second side surface of the semiconductor chip 100 may be substantially flat from a point on the side surface of the substrate 101 to the edge of the back surface of the semiconductor chip 100. Accordingly, a line passing through a plurality of points on the first side surface GC may be oblique with respect to a line passing through a plurality of points on the second side surface. The angle between the first side surface GC and the second side surface may be an obtuse angle. The first side surface GC may have a flat shape with rougher roughness compared to the second side surface. The first side surface GC may be a sloped side surface.

Depending on the width of the scribe lane area Kf, the width W_GC of the first side surface GC of the semiconductor chip 100 in the lateral direction (for example, X-direction) of the semiconductor chip 100 may be greater than 3 μm and less than 100 μm. Depending on the total thickness of the semiconductor chip 100 or the thickness of the pad layer 190, the height D_GC of the first side surface GC of the semiconductor chip 100 in the front-back direction (for example, Z-direction) of the semiconductor chip 100 may be greater than 10 μm and less than 300 μm. For example, the total thickness of the interconnection structure 180 and the pad layer 190 may be 20 μm or less and may be thinner than the height D_GC of the first side surface GC. For example, in some embodiments, the total thickness of the semiconductor chip 100 (e.g., from a topmost surface to a bottommost surface) may be greater than 20 μm and less than or equal to 300 μm, and may be thicker than twice the height D_GC of the first side surface GC.

For example, the width W_GC, height D_GC, thickness, and roughness may respectively be measured by analysis using at least one of Transmission Electron Microscopy (TEM), Atomic Force Microscope (AFM), Scanning Electron Microscope (SEM), optical microscope, and surface profiler, and may be calculated by the average value of the corresponding pixels in the image obtained by the above analysis.

The width W_GC of the first side surface GC of the semiconductor chip 100 in the lateral direction (for example, X-direction) of the semiconductor chip 100 may be more than 0.1 times but less than 1 times the height D_GC of the first side surface GC of the semiconductor chip 100 in the front-back direction (for example, Z-direction) of the semiconductor chip 100. For example, the ratio of the width W_GC and the height D_GC (for example, aspect ratio) may be determined by how many times laser irradiation is performed when forming the first side surface GC, and more than 0.1 times and less than 1 times may be the ratio (for example, aspect ratio) of the first side surface GC formed by laser irradiation being performed twice or less.

Referring to FIGS. 4A to 4C, the interconnection structure 180 on the substrate 101 includes an interconnection line 185 and an interconnection insulating layer 181, and the pad layer 190 may include a pad 195 and a pad insulating layer 191.

The substrate 101 may include a semiconductor such as silicon. For example, the substrate 101 may include a device layer DL, and the device layer DL may include various impurity regions for individual devices and a device isolation structure such as a shallow trench isolation (STI) structure. The semiconductor is not limited to silicon and may be at least one of germanium, silicon carbide (SiC), gallium arsenide (GaAs), indium arsenide (InAs), and indium phosphide (InP). For example, the device may include Planar MOSFET (Metal Oxide Semiconductor FET), FinFET whose active area has a fin structure, Multi Bridge Channel FET (MBCFET™) including a plurality of channels stacked vertically on the active area, or gate-all-around (Gate-All-Around) transistor, or Vertical FET (VFET), but is not limited thereto.

For example, the interconnection insulating layer 181 may include at least one of silicon oxide (SiO), silicon nitride (SiN), silicon oxynitride (SiON), silicon oxycarbide (SiOC), and silicon carbonitride (SiCN). The space not occupied by the interconnection line 185 within the interconnection structure 180 may be filled. The interconnection line 185 may include an interconnection pattern (182 in FIG. 5B) extending in the lateral direction (for example, X-direction) and an interconnection via (183 in FIG. 5B) extending in the front-back direction (for example, Z-direction), and may be electrically connected to the device layer DL. For example, the interconnection line 185 may include at least one of copper (Cu), copper alloy, aluminum (Al), and aluminum alloy. The metal material is not limited thereto, and may be implemented as at least one of nickel (Ni), gold (Au), cobalt (Co), tantalum (Ta), tellurium (Te), titanium (Ti), tungsten W or alloys thereof (for example, TiN, TaN).

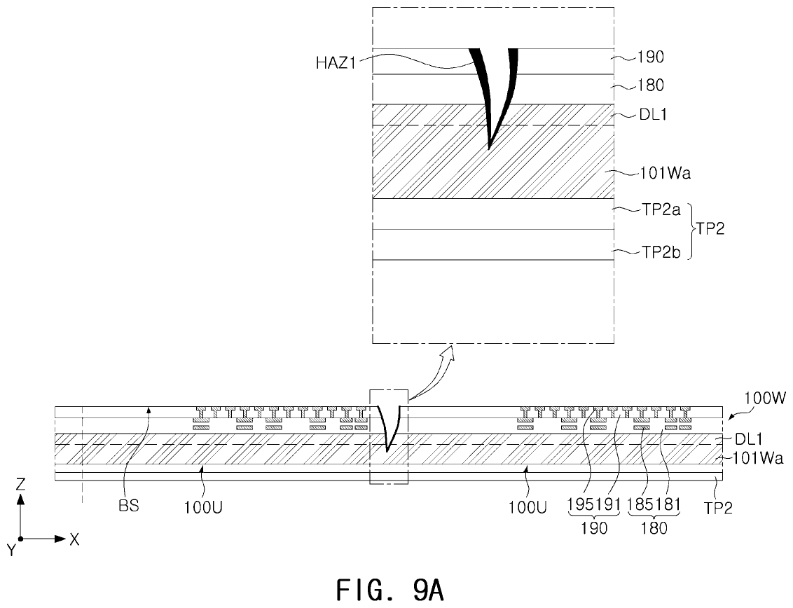

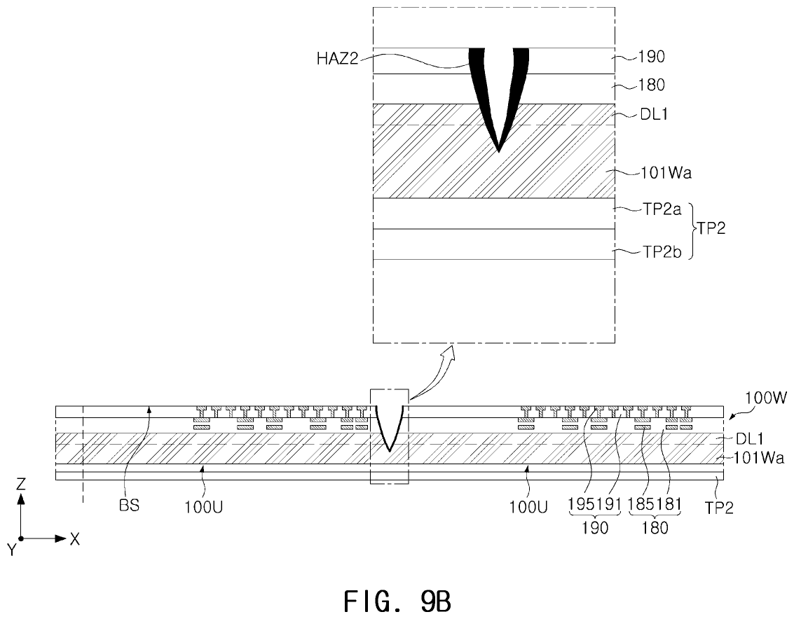

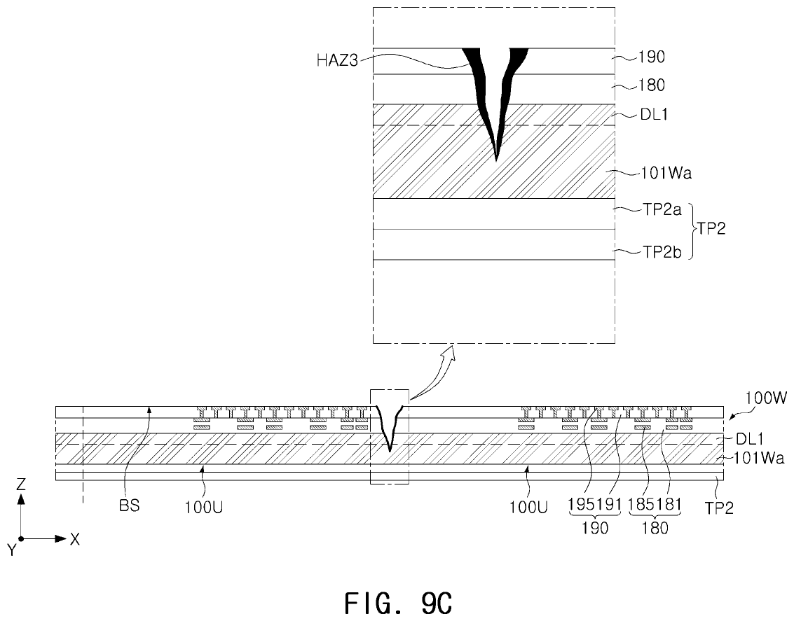

The pad 195 may be disposed on the front (upper surface) of the interconnection structure 180 and may be electrically connected to the interconnection line 185. The pad 195 may include copper (Cu) or a copper alloy, but is not limited thereto, and may include a metal material that the interconnection line 185 may include. The pad insulating layer 191 may surround the pad 195. Each of the interconnection insulating layer 181 and the pad insulating layer 191 may include at least one of SiO₂, SiN, SiCN, and tetraethyloxysilane (TEOS). Depending on the design (for example, pad 1121 in FIG. 9), pad 195 may be disposed on the front surface BS of semiconductor chip 100.

Referring to FIG. 4B, the semiconductor chip 100b of the semiconductor package according to example embodiments may not have the heat affected zone HAZ of FIG. 4A. For example, the heat affected zone HAZ of FIG. 4A may be removed or reduced by additional processes (for example, side surface cleaning process, side surface polishing process). The first side surface GC of the semiconductor chip 100b may be oblique with respect to the second side surface of the semiconductor chip 100b from a point on the side surface of the substrate 101 to the edge of the back surface of the semiconductor chip 100b, or may be more curved than the second side surface.

Referring to FIG. 4C, the semiconductor chip 100c of the semiconductor package according to example embodiments may have a substrate 101 that is thinner than the substrate 101 of FIG. 4A. The total thickness of the semiconductor chip 100c may be thicker than the height D_GC of the first side surface GC but may be thinner than twice the height D_GC. For example, the substrate 101 of FIG. 4C may be implemented by further extending the time required for the thickness reduction operation of FIG. 2C.

FIGS. 5A to 5C are cross-sectional views illustrating a structure in which the memory chip 200 is disposed on the front surface BS of the semiconductor chip 100 of the semiconductor package 300 or 1000 according to example embodiments. FIG. 5B is a partially enlarged view illustrating a portion (A) of the semiconductor package illustrated in FIG. 5A, and FIG. 5A is a cross-section of the semiconductor package taken along line I-I′ in FIG. 5C. FIG. 5C illustrates a semiconductor package 1000 in which four (but not limited to four) semiconductor packages 300 of FIGS. 5A and 5B are stacked in the front-back direction (for example, Z-direction). The semiconductor chip 100 of FIGS. 5A to 5C may be the same as the semiconductor chip 100 of FIG. 4A, but is not limited thereto.

Referring to FIGS. 5A and 5B, the semiconductor package 300 according to example embodiments may include a memory chip 200 and the semiconductor chip 100.

The front surface (upper surface) of the semiconductor chip 100 may be the front surface BS. The first side surface GC of the semiconductor chip 100 may be inclined with respect to the second side surface of the semiconductor chip 100 (lower side surface of the substrate 101) or may be more curved than the second side surface, and may be oblique or more curved with respect to the front (upper) surface of the semiconductor chip 100 or the front (upper) surface of the memory chip 200. The semiconductor chip 100 and memory chip 200 may be considered to be a semiconductor chip (e.g., a cell-on-peripheral memory chip), for example having a memory region and a peripheral region hybrid-bonded to each other. In this case the semiconductor device formed by the combined chip may have a first side surface that is a continuously sloped side surface CG that includes all of the side surface of the memory chip 200 and part of the side surface of the semiconductor chip 100, and may have a second side surface that is perpendicular to a front surface BS of the semiconductor chip 100. The first side surface and second side surface may exhibit the properties and orientations of the first side surface and second side surface discussed in connection with FIGS. 4A-4C. A top surface of the cell-on-peripheral memory chip may be described as a front surface of the cell-on-peripheral memory chip.

Referring to FIGS. 5A and 5B, the memory chip 200 of the semiconductor package 300 according to example embodiments may be disposed on an area surrounded by an edge area of the front surface BS of the semiconductor chip 100. For example, the width W of the edge area may range from 5 μm to 50 μm. Preferably, the width W of the edge area may be in the range of 10 μm to 30 μm.

A protective insulating layer 310 is disposed on the upper surface of the memory chip 200, and a connection pad 350 may be formed on the protective insulating layer 310 to be electrically connected to memory cells (for example, through plate layer 210). The thickness t1 of the protective insulating layer 310 may be smaller than the width W of the edge area. In particular, the thickness t2 of the protective insulating layer 310 located on the side surface of the memory chip 200 may be smaller than the width W of the edge area.

The semiconductor package 300 according to this embodiment may be a memory device in which memory cells are arranged in three dimensions, and the memory cells employed in the memory chip may have a three-dimensional memory cell structure.

Referring to FIG. 5B, the device layer DL may include source/drain regions 105 and device isolation layers 110 within the substrate 101, and circuit elements 120 disposed on the substrate 101. The substrate 101 may have an upper surface extending in the X-and Y-directions. The substrate 101 may have an active region defined by device isolation layers 110. Source/drain regions 105 doped with impurities may be disposed in the active region. The substrate 101 may include a semiconductor material, for example, a group IV semiconductor, a group III-V compound semiconductor, or a group II-VI compound semiconductor. For example, the substrate 101 may be provided as a single crystal bulk wafer.

In some embodiments, circuit elements 120 may include planar transistors. Each circuit element 120 may include a circuit gate dielectric layer 122, spacer layers 124, and a circuit gate electrode 125. Source/drain regions 105 may be disposed within the substrate 101 on both side surfaces of the circuit gate electrode 125.

The interconnection structure 180 may include an interconnection insulating layer 181 and an interconnection line 185 disposed on the interconnection insulating layer 181. The interconnection line 185 may include interconnection patterns 182 and an interconnection via 183 (or a ‘contact plug’) for inter-layer connection. The interconnection line 185 may be connected to the circuit elements 110 through an interconnection via 183 (for example, a contact plug).

The pad layer 190 may include a pad 195 and a pad insulating layer 191 surrounding a side surface of the pad 195. The pad 195 may include a bonding via 193 to be connected to the interconnection line 185 of the interconnection structure 180. In some embodiments, the bonding vias 193 may have a cylindrical shape, and the pad 195 may have a line shape or a pad shape with a relatively large area. The bonding vias 193 and pad 195 may include a conductive material, for example, copper (Cu).

The upper surfaces of the pads 195 may have flat surfaces exposed to the upper surface of the semiconductor chip 100. The pad 195 may be configured so that the area required for bonding overlaps with the bonding metal layer 295 of the memory chip 200 at a position corresponding to the pad 195. In some embodiments, the pad 195 may have an area that substantially corresponds to the area of the bonding metal layer 295. Additionally, the bonding vias 193 and pad 195 may provide a path for electrical connection with the memory chip 200. In some embodiments, some of the pads 195 may not be connected to the lower circuit interconnection lines 185 but may be provided for bonding.

Referring to FIG. 5B, the memory chip 200 includes a bonding structure 290 for bonding to the semiconductor chip 100, similar to the pad layer 190 of the semiconductor chip 100. The bonding structure 290 includes bonding metal layers 295 each bonded to the pad 195, and a bonding insulating layer 291 surrounding the side surfaces of the bonding metal layers 295 and bonded to the pad insulating layer 191.

The bonding metal layers 295 may have a flat surface exposed to the lower surface of the memory chip 200. The bonding metal layers 295 may be bonded and electrically connected to the pad 195 of the semiconductor chip 100. The bonding vias 293 and the bonding metal layers 295 may include a conductive material, for example, copper (Cu).

The bonding insulating layer 291 may provide dielectric-dielectric bonding with the bonding insulating layer 291 of the memory chip 200, similar to the pad insulating layer 191, and may include at least one of, for example, SiO, SiN, SiCN, SiOC, SiON, and SiOCN. The combination of dielectric-dielectric bonding and copper (Cu)-copper (Cu) bonding may be hybrid bonding.

Bonding metal layers 295 may be electrically connected to memory cells (for example, vertical channel structure CH and gate electrodes 240) through bonding vias 293. In detail, the bonding vias 293 may be disposed below the interconnection structure 280 and connected to interconnection lines (or cell interconnection lines) 285.

In this embodiment, the device layer DL of the memory chip 200 may include a three-dimensional memory cell structure and a molding insulating layer 270 surrounding the three-dimensional memory cell structure.

In detail, referring to FIG. 5B, the memory cell structure of the memory chip 200 may include a plate layer 210 having a first region R1 and a second region R2, first and second horizontal conductive layers 212 and 214 on the lower surface of the plate layer 210, gate electrodes 230 stacked on the lower surfaces of the first and second horizontal conductive layers 212 and 214, gate electrodes 230 and interlayer insulating layers 225 alternately stacked, separation regions (not illustrated) extending in one direction through the gate electrodes 230, vertical channel structures CH disposed to penetrate the gate electrodes 230 in the first region R1, and input/output contact structures 250A and 250B disposed to penetrate the plate layer 210 and the gate electrodes 230 in the second region R2. The memory chip 200 may include a base insulating layer 215 on the upper surface of the plate layer 210.

The memory chip 200 is a second interconnection structure 280, and may further include gate contacts 260 connected to the gate electrodes 230 and cell interconnection lines 285 including cell contact plugs 283 located in the second region R2. The cell contact plugs 283 are structures that connect layers and may have a cylindrical shape. The cell contact plugs 283 may have different lengths depending on the connection target (position). The gate contacts 260, the cell contact plugs 283, and the cell interconnection lines 282 may include, for example, tungsten W, aluminum (Al), copper (Cu), tungsten nitride (WN), tantalum nitride (TaN), titanium nitride (TiN), or combinations thereof.

The first region R1 of the plate layer 210 is a region where the gate electrodes 230 are vertically stacked and the channel structures CH are disposed, and may be a memory cell region where memory cells are disposed. The second region R2 of the plate layer 210 is a region where the gate electrodes 230 extend to different lengths and may correspond to a connection area for electrically connecting the memory cells to the semiconductor chip 100. The second region R2 may be located at least one end of the first region RI in at least one direction, for example, the X-direction.

The plate layer 210 may have a structure that continuously extends throughout the semiconductor package 300 as illustrated in FIG. 5A. The plate layer 210 may include a conductive material. For example, the plate layer 210 may include a semiconductor material, such as a group IV semiconductor, a group III-V compound semiconductor, or a group II-VI compound semiconductor. For example, Group IV semiconductors may include silicon, germanium, or silicon-germanium. The plate layer 210 may further include impurities. The plate layer 210 may be provided as a polycrystalline semiconductor layer, such as a polycrystalline silicon layer, or an epitaxial layer.

The first and second horizontal conductive layers 212 and 214 may be sequentially stacked and disposed on the lower surface of the first region R1 of the plate layer 210. The first horizontal conductive layer 212 may not extend into the second region R2 of the plate layer 210, and the second horizontal conductive layer 214 may extend into the second region R2. The first horizontal conductive layer 212 may function as part of a common source line of the semiconductor package 300, and in some embodiments, may function as a common source line together with the plate layer 210. The first horizontal conductive layer 212 surrounds the channel layer 240 and may be directly connected to the channel layer 240.

The second horizontal conductive layer 214 may contact the plate layer 210 in some areas where the first horizontal conductive layer 212 and the horizontal insulating layer 220 are not disposed. The second horizontal conductive layer 214 covers the ends of the first horizontal conductive layer 212 or the horizontal insulating layer 220 in some areas and may be bent to extend onto the lower surface of the plate layer 210.

The first and second horizontal conductive layers 212 and 214 may include a semiconductor material. For example, the first and second horizontal conductive layers 212 and 214 may both include polycrystalline silicon doped with impurities. In some embodiments, the material of the second horizontal conductive layer 104 is not limited to a semiconductor material and may also be replaced with an insulating layer.

The horizontal insulating layer 220 may be disposed on the lower surface of the plate layer 210 at a level that overlaps the first horizontal conductive layer 212 in at least a portion of the second region R2. The horizontal insulating layer 220 is alternately stacked on the second region R2 of the plate layer 210 and may include first and second insulating layers made of different materials. For example, the horizontal insulating layer 220 may include silicon oxide, silicon nitride, silicon carbide, or silicon oxynitride. In some embodiments, the first insulating layers may be made of the same material as the interlayer insulating layers 225, and the second insulating layers may be made of a different material from the interlayer insulating layers 225.

The gate electrodes 230 may be stacked vertically apart on the lower surface of the plate layer 210 to form a stacked structure together with the interlayer insulating layers 225. The stacked structure is vertically stacked and may include lower and upper stacked structures surrounding the first and second channel structures CH1 and CH2, respectively.

The gate electrodes 230 may include at least one lower gate electrode 230L forming the gate of the ground selection transistor, memory gate electrodes 230M forming a plurality of memory cells, and upper gate electrodes 230U forming the gates of the string selection transistors. In some embodiments, the gate electrodes 230 may include a gate electrode disposed below the upper gate electrodes 230U and/or on the lower gate electrode 230L and constituting an erase transistor used in an erase operation using the gate induced leakage current (Gate Induced Drain Leakage, GIDL) phenomenon.

The gate electrodes 230 are stacked vertically on the first region R1 and the second region R2 and spaced apart from each other, and extend at different lengths from the first region R1 to the second region R2. A stepped structure in the form of steps may be formed in a portion of the second region R2. The gate electrodes 230 may be disposed to have a stepped structure in the Y-direction. Due to the stepped structure, the upper gate electrode 230 of the gate electrodes 230 extends longer than the lower gate electrode 230, and the gate electrodes 230 may each have regions whose lower surfaces are exposed downward from the interlayer insulating layers 225 and other gate electrodes 230, and these regions may also be referred to as “gate pad areas.” The gate pad area may correspond to a portion of the gate electrode 230 located at the bottom of each area among the gate electrodes 230 forming the stacked structure in the second region R2 of the plate layer 210. The gate electrodes 230 may be connected to gate contacts 260 in the gate pad areas.

The gate electrodes 230 may include a metal material, for example, tungsten W. In some embodiments, the gate electrodes 230 may include polycrystalline silicon or metal silicide material. In some embodiments, the gate electrodes 230 may further include a diffusion barrier, for example, the diffusion barrier may include tungsten nitride (WN), tantalum nitride (TaN), titanium nitride (TiN), or combinations thereof.

The interlayer insulating layers 225 may be disposed between the gate electrodes 230. Similar to the gate electrodes 230, the interlayer insulating layers 225 may be disposed to be spaced apart from each other in a direction perpendicular to the lower surface of the plate layer 210 and extend in the X-direction. For example, the interlayer insulating layers 225 may include an insulating material such as silicon oxide or silicon nitride.

Each of the vertical channel structures CH may have first and second channel structures CH1 and CH2 connected to each other, penetrating the lower and upper stacked structures of the gate electrodes 130, respectively, and may have bends with different widths in the connection area.

Each of the channel structures CH may include a channel layer 140, gate dielectric layers (not shown), a channel buried insulating layer 247, and a channel pad 249 disposed within the channel hole. The channel layer 240 may be formed as an annular shape surrounding the internal channel-filled insulating layer 247, but may also have another shape, such as a cylinder or a prism, without the channel-filled insulating layer 247. A lower portion of the channel layer 240 may be connected to the first horizontal conductive layer 212. For example, the channel layer 240 may include a semiconductor material such as polycrystalline silicon or single crystalline silicon.

The gate dielectric layer may be disposed between the gate electrodes 230 and the channel layer 240. The gate dielectric layer may extend vertically along channel layer 240. The gate dielectric layer may include a portion of a tunneling layer, a charge storage layer, and a blocking layer sequentially stacked from the channel layer 240. The tunneling layer may tunnel charges into the charge storage layer and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include silicon oxide (SiO₂), silicon nitride (Si₃N₄), silicon oxynitride (SiON), high-K dielectric material, or a combination thereof.

The channel pad 249 may be disposed only on the lower end of the lower second channel structure CH2. Channel pads 249 may include, for example, doped polycrystalline silicon. The channel layer 240, the gate dielectric layer, and the channel buried insulating layer 247 may be connected to each other between the first channel structure CHI and the second channel structure CH2. An interlayer insulating layer 225 having a relatively large thickness may be further disposed between the first channel structure CH1 and the second channel structure CH2.

As illustrated in FIG. 5B, the input/output contact structures 250A and 250B may be disposed to be spaced apart from the vertical channel structures CH in the X-direction. The first input/output contact structures 250A may be disposed around the gate contacts 260 and may be disposed in an area including an area between adjacent gate contacts 260 in the X-direction. The first input/output contact structures 250A may be disposed to penetrate the plate layer 210, the horizontal insulating layer 220, the second horizontal conductive layer 214, and the gate electrodes 230, in the second region R2. The first input/output contact structures 250A may electrically connect the circuit elements 120 of the semiconductor chip 100 and the input/output pad (not illustrated). The first input/output contact structures 250A may be disposed to overlap the input/output pads (not illustrated) in the Z-direction. In this embodiment, the second input/output contact structures 250B may electrically connect the circuit elements 120 of the semiconductor chip 100 and the connection pad 350 for input/output through the plate layer 210.

The connection pad 350 may be connected to the input/output contact structures 250A and 250B through pad vias 353. The connection pad 350 may be connected to an electrical connection structure, such as a signal transmission medium of the device, such as the package substrate 1100, through the upper surface of the semiconductor package 300 (see FIG. 5C).

As previously described, a protective insulating layer 310 is disposed on the upper surface of the memory chip 200, and the protective insulating layer 310 may extend along the side surface of the memory chip 200 to the edge area of the semiconductor chip 100.

As illustrated in FIG. 5B, the protective insulating layer 310 may include an insulating capping layer 312 disposed on the upper and side surfaces of the memory chip 200, a passivation layer 315 disposed on the insulating capping layer 312, and a barrier insulating film 314 disposed between the insulating capping layer 312 and the passivation layer 315. The connection pad 350 is disposed on the insulating capping layer 312, and the passivation layer 315 and the barrier insulating layer 314 may be configured to expose a portion of the connection pad 350. For example, the insulating capping layer 312 may include silicon oxide, and the passivation layer 315 may include polyimide or a polyimide-based material. Additionally, the barrier insulating film 314 may include, for example, silicon nitride or a silicon nitride-based material.

Each of the semiconductor packages 300 illustrated in FIG. 5C may include a semiconductor chip 100 having a peripheral circuit and a memory chip 200 having two memory cell arrays MCs arranged in the Y-direction. However, the number of memory cell arrays MCs is not limited to two, and can be one, or three or more. As described above, the memory chip 200 is bonded to the inner area of the upper surface of the semiconductor chip 100 excluding the edge area, so the step structure may be confirmed from the side surface of the semiconductor package 300.

The semiconductor package 1000 may include a package substrate 1100, semiconductor packages 300 on the package substrate 1100, wires 1400 (e.g., bonding wires) electrically connecting the semiconductor packages 300 and the package substrate 1100, and a molded layer 1500 covering the semiconductor packages 300 and wires 1400 on the package substrate 1100. The package substrate 1100 may be a printed circuit board including electrical connection structures 1130 on the upper of the package. Each semiconductor package 300 may include a connection pads 350 for input and output. The semiconductor packages (e.g., semiconductor sub-packages such as 300) according to this embodiment are not limited arrangement shown in the semiconductor package 1000 illustrated in FIG. 5C, and may be employed in various other semiconductor packages in other manners.

In the previous embodiments, the semiconductor package 300 is illustrated as a non-volatile memory device in which memory cells are arranged in three dimensions, but the inventive concepts disclosed herein can also be applied to other memory devices such as DRAM devices or other semiconductor packages such as logic elements. For example, in the case of a DRAM device, a semiconductor package in which a semiconductor chip having DRAM cells and a memory chip including peripheral circuits (or capacitors) are bonded at the wafer level may also have a structure similar to the previous embodiment.

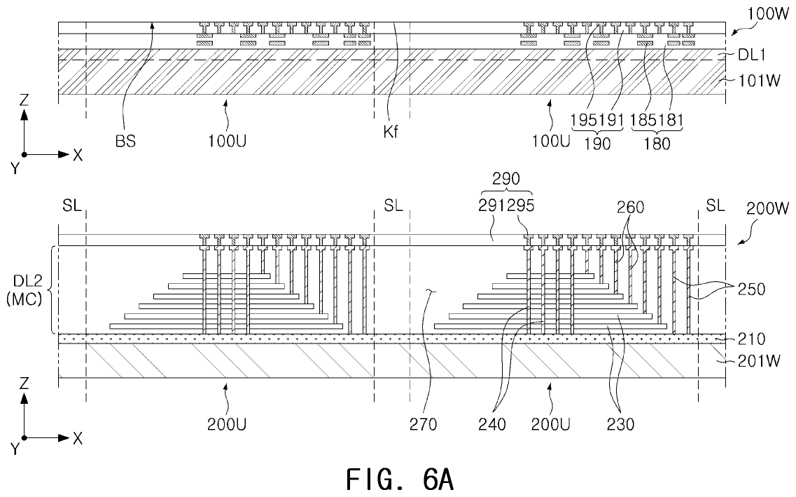

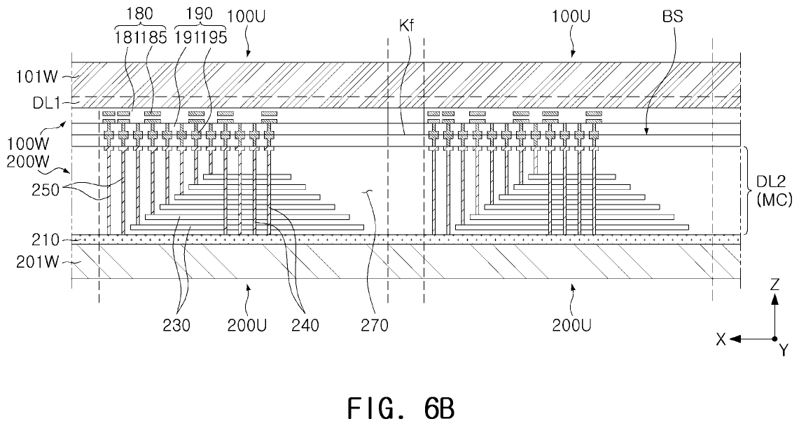

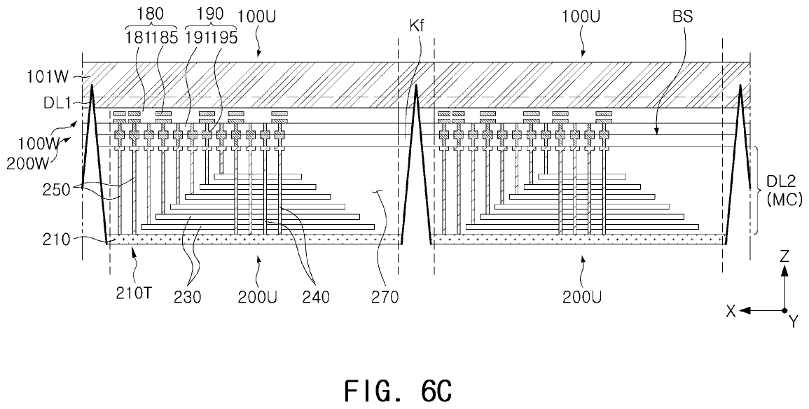

FIGS. 6A to 6C illustrate a method of manufacturing a semiconductor package according to example embodiments, and may be used for manufacturing the semiconductor package 300 of FIG. 5A, but the embodiments are not limited thereto.

Referring to FIG. 6A, the memory wafer 200W may include a plurality of memory chip areas 200U, and each of the plurality of memory chip areas 200U may correspond to the memory cell array MC of FIG. 1A. The memory wafer 200W may be provided by a process of forming a second device layer DL2 on the second substrate 201W and forming a bonding structure 290 having bonding metal layers 295 on the second device layer DL2 and a bonding insulating layer 291 surrounding the second bonding metal layers 295. Although not illustrated in this embodiment, an additional interconnection structure (see 280 in FIG. 5B) having a cell contact plug or interconnection line may be disposed between the second device layer DL2 and the bonding structure 290.

Referring to FIG. 6B, a memory wafer 200W is bonded on the front surface BS of the wafer 100W. This bonding process may be performed by a hybrid bonding process, as described above. By heating the bonding metal layers 295 and the bonding insulating layer 291 while bonded to the pad 195 and the pad insulating layer 191, respectively, under constant pressure, the plurality of portions 100U and the plurality of memory chip areas 200U may be bonded to each other. Depending on the design, the plurality of memory chip areas 200U of the memory wafer 200W may be bonded to the wafer 100W while being substantially separated.

Referring to FIG. 6C, the second substrate 201W is removed from the memory wafer 200W. The semiconductor package 300 according to this embodiment may require a pad formation process for external connection. As a method for forming the pad, the second substrate 201W may be removed to expose the surface of the second device layer DL2, as in the present process. In this embodiment, the upper surface 210T of the plate layer 210 may be exposed. This process may be performed using chemical-mechanical polishing (CMP) or grinding processes.

Referring to FIG. 6C, the operation of forming a groove in the method of manufacturing a semiconductor package according to example embodiments may be the same as the operation of forming the groove described above with reference to FIGS. 2A and 3D, and may be performed after removing the second substrate 201W. The plurality of portions 100U of the wafer 100W may be separated by the method of manufacturing a semiconductor package of FIGS. 2A to 2E, or may be separated by the method of manufacturing a semiconductor package of FIGS. 3A to 3D. Accordingly, the semiconductor package 300 of FIG. 5A may be manufactured, but this method is not limited to the embodiment of FIG. 5A.

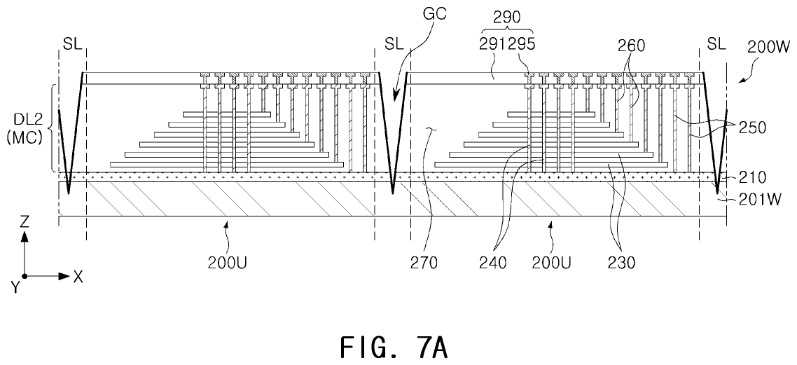

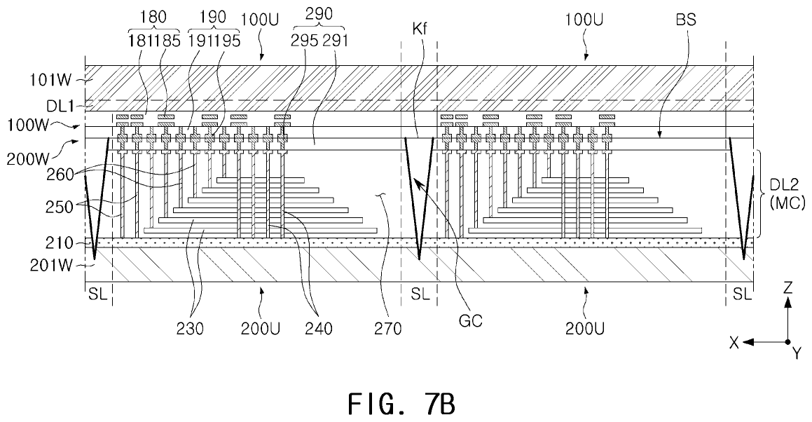

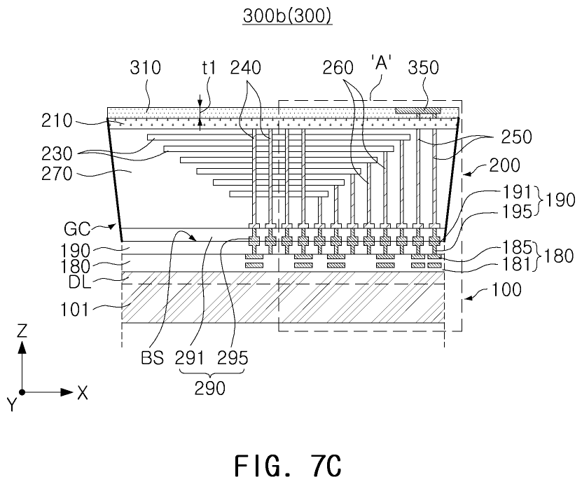

FIGS. 7A and 7B illustrate a method of manufacturing a semiconductor package according to example embodiments, and FIG. 7C illustrates a semiconductor package 300b according to example embodiments. The semiconductor package being manufactured in FIGS. 7A and 7B may be manufactured from the semiconductor package being manufactured in FIG. 6A to be manufactured into the semiconductor package 300b of FIG. 7C. The semiconductor package 300b according to example embodiments illustrated in FIG. 7C is not limited to the method of manufacturing a semiconductor package illustrated in FIGS. 7A and 7B.

Referring to FIG. 7A, the operation of forming a groove in the method of manufacturing a semiconductor package according to example embodiments may include forming a groove in the front surface of the memory wafer 200W using a laser, and may be the same as the operation of forming the groove described above with reference to FIGS. 2A and 3D.

Referring to FIG. 7B, the wafer 100W may be bonded to the memory wafer 200W on which the groove is formed, and may be the same as the bonding between the wafer 100W and the memory wafer 200W described above with reference to FIG. 6C. Afterwards, a separation process for the scribe lane area Kf of the wafer 100W (for example, dicing using a blade with a predetermined width, or dicing using laser and/or chemical etching involving removal of an area of a predetermined width) may be performed. This separation process may separate the wafer 100W as well as the substrate 101W.

The plurality of memory chip areas 200U of the memory wafer 200W may be separated by the separating step illustrated in FIG. 2E (e.g., after the scribe lane area Kf cutting of the wafer 100W as discussed above). Referring to FIG. 7C, the semiconductor package 300b according to example embodiments may include a semiconductor chip 100 and a memory chip 200. At least a portion of the first side surface GC of the semiconductor package 300b may be inclined with respect to a side surface of the semiconductor chip 100 (side surface of the substrate 101, which may be a lower side surface of the semiconductor package 200b) or may be more curved than the side surface of the semiconductor chip 100, and may be oblique or more curved with respect to the front (upper) surface of the semiconductor chip 100 or the front surface (upper surface) of the memory chip 200.

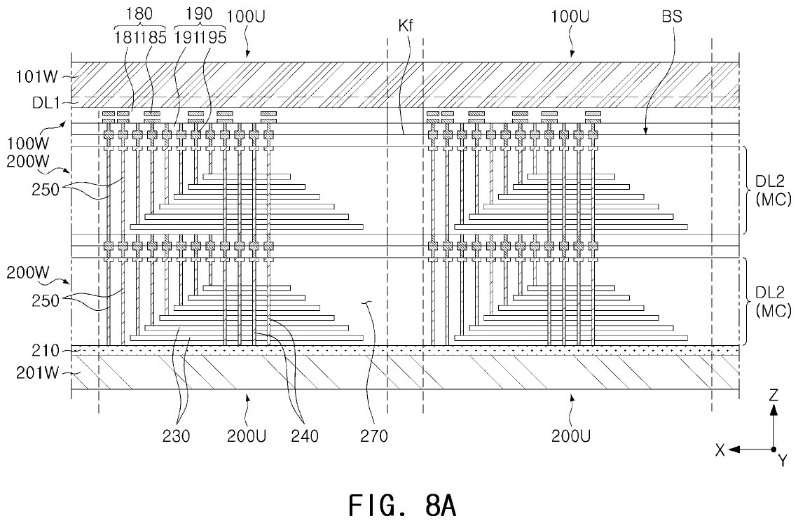

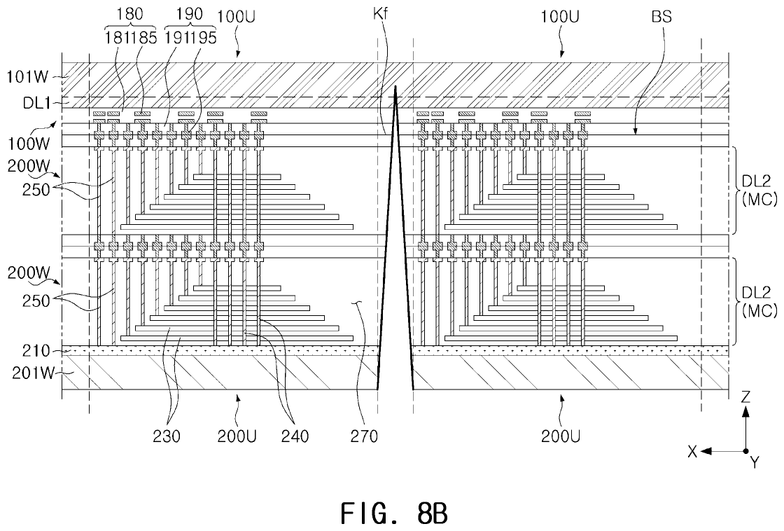

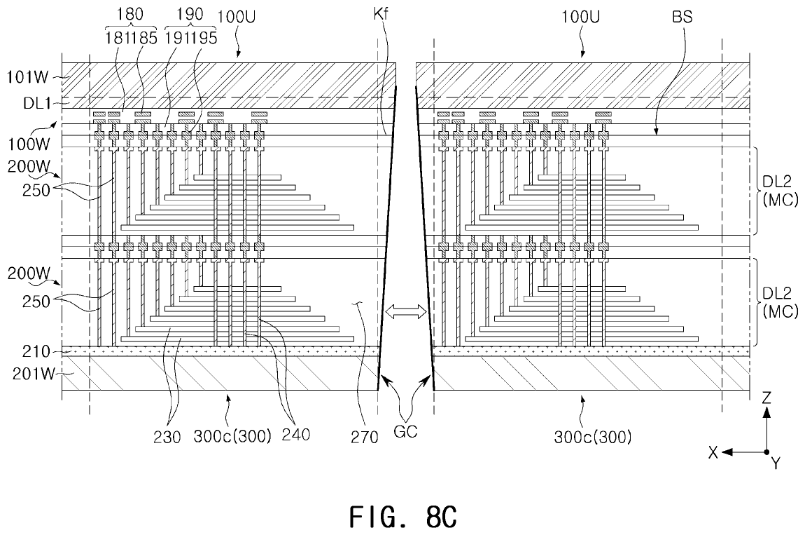

FIGS. 8A and 8B illustrate a method of manufacturing a semiconductor package according to example embodiments, and FIG. 8C illustrates a plurality of semiconductor packages 300c according to example embodiments. The semiconductor package being manufactured in FIGS. 8A and 8B may be manufactured from the semiconductor package being manufactured in FIG. 6B into a plurality of semiconductor packages in FIG. 8C, but the plurality of semiconductor packages according to the example embodiment illustrated in FIG. 8C are not limited to the method of manufacturing a semiconductor package illustrated in FIGS. 8A and 8B.

Referring to FIGS. 6B and 8A, the second substrate 201W is removed from the memory wafer 200W of FIG. 6B, the plate layer 210 is removed, and an additional memory wafer 200W may be further bonded to the removed location. For example, a structure similar to the bonding structure 290 of FIG. 6A may be disposed between the plurality of memory wafers 200W to provide electrical connection paths between the plurality of memory wafers 200W.

Referring to FIG. 8b, the operation of forming a groove in the method of manufacturing a semiconductor package according to example embodiments may include forming a groove in the front surface of the wafer 100W and a plurality of memory wafers 200W using a laser, and may be the same as the operation of forming the groove described above with reference to FIGS. 2A and 3D. The groove may penetrate a plurality of memory wafers 200W. A plurality of memory wafers 200W may be included on the wafer 100W.

Referring to FIG. 8C, the plurality of portions 100U of the wafer 100W may be separated by the separating step illustrated in FIG. 2E, and thus, the plurality of memory chip areas 200U of each of the plurality of memory wafers 200W may also be separated from each other. Each semiconductor package of semiconductor packages 300c according to example embodiments may include a plurality of memory chips 200 and a semiconductor chip 100. The first side surface GC of the semiconductor chip 100 as well as a side surface of the memory chips 200 may be inclined with respect to the second side surface of the semiconductor chip 100 (lower side surface of the substrate 101) or may be more curved than the second side surface. The front (upper) surface of the semiconductor chip 100 may be the front (upper) surface of the memory chip disposed furthest from the pad layer 190 among the plurality of memory chips 200.

FIGS. 9A to 9C are cross-sectional views illustrating various shapes of grooves (or heat affected zones (HAZ1, HAZ2, HAZ3)) of a semiconductor package and a method of manufacturing a semiconductor package according to example embodiments. Various shapes of the grooves (or heat-affected zones (HAZ1, HAZ2, HAZ3)) of FIGS. 9A to 9C may be implemented by process distribution of the semiconductor package and method of manufacturing a semiconductor package of FIGS. 2A to 8C, and thus, may replace the groove (or heat affected zone HAZ) of the semiconductor package and method of manufacturing a semiconductor package of FIGS. 2A to 8C, but embodiments are not limited thereto.

Referring to FIGS. 9A to 9C, the first side surface of the semiconductor chip 100 (location of the heat affected zones HAZ1, HAZ2, HAZ3) from a point on the side surface of the substrate 101 to the edge of the front surface BS of the semiconductor chip 100 may be more curved than the second side surface of the semiconductor chip 100 from a point on the side surface of the substrate 101 to the edge of the back surface of the semiconductor chip 100. The first side surface (location of the heat affected zones HAZ1, HAZ2 and HAZ3) may be more curved than the front surface BS, and the second side surface may be perpendicular to the front surface BS. The first side surface may have a heat affected zone (HAZ1, HAZ2, HAZ3), and a point on the side surface of the substrate 101 may be the back-end of the heat affected zone (HAZ1, HAZ2, HAZ3).

How curved the side surface is may be measured by the differential value at each point on the side surface. For example, in an image obtained through analysis using at least one of TEM, AFM, SEM, optical microscopy, and surface profiler for a cross section of a semiconductor package, the side surfaces of a semiconductor chip may be identified with the naked eye or through image processing (for example, extracting points of rapid changes in brightness between pixels). Thereafter, the convex portion or concave portion may be identified based on the differential values of each point on the identified side surface. Afterwards, a parameter representing the degree of curvedness of the side surface may be calculated based on the difference between the peak values of the differential value in the convex or concave part.

Referring to FIG. 9A, one side surface of the heat affected zone HAZ1 may be concave, and the other side surface of the heat affected zone HAZ1 may be convex. Referring to FIG. 9B, the heat affected zone HAZ2 may be concave on both side surfaces. Depending on the design, the heat affected zone may be convex on both side surfaces. Referring to FIG. 9C, the heat-affected zone HAZ3 may be in an embossing form, and may be in a form in which concave and convex shapes are alternately formed up and down.

FIG. 10A is a cross-sectional view illustrating a structure in which a plurality of semiconductor chips 100 of a semiconductor package 1000b are connected to each other through direct bonding according to example embodiments. For example, the semiconductor package 1000b may be at least a part of a High Bandwidth Memory (HBM) and may be electrically connected to an interposer or a printed circuit board.

For example, some of the plurality of semiconductor chips 100 may be a volatile memory chip, such as Dynamic Random Access Memory (DRAM) or Static Random Access Memory (SRAM), or may be a non-volatile memory chip such as Phase-change Random Access Memory (PRAM), Magnetoresistive Random Access Memory (MRAM), Ferroelectric Random Access Memory (FeRAM), or Resistive Random Access Memory (RRAM). For example, one of the plurality of semiconductor chips 100 may be a logic chip such as a microprocessor, an analog element, or a digital signal processor.

Referring to FIG. 10A, at least one of the plurality of semiconductor chips 100 may further include at least one of through electrodes 153, a back pad 152, and a back insulating layer 151. The plurality of first side surfaces GC from a point on the side surface of the substrate 101 of each of the plurality of semiconductor chips 100 to the edge of the front surface of each of the plurality of semiconductor chips 100 may be oblique with respect to the plurality of second side surfaces from a point on the side surface of the substrate 101 of each of the plurality of semiconductor chips 100 to the edge of the back surface of each of the plurality of semiconductor chips 100, or may be more curved than the plurality of second side surfaces.

Each of the through electrodes 153 may have a pillar structure that penetrates the substrate 101. The front end of the through electrodes 153 may be electrically connected to the device layer DL or the interconnection structure 180, and the rear end of the through electrodes 153 may be electrically connected to the rear pad 152. For example, each of the through electrodes 153 may include a via plug and an insulating liner surrounding the via plug.

For example, the rear pad 152 may be implemented in a similar manner to the pad (195 in FIG. 4A) of the pad layer 190, and the rear insulating layer 151 may be implemented in a similar manner to the pad insulating layer (191 in FIG. 4A) of the pad layer 190.

FIG. 10B is a cross-sectional view illustrating a structure in which the semiconductor chip 100 of the semiconductor package 1000c is electrically connected to a redistribution line according to example embodiments.

Referring to FIG. 10B, the semiconductor chip 100 may be mounted on the redistribution structure 1110 in a flip-chip structure. The semiconductor package 1000c may include at least one of a redistribution structure 1110, electrical connection structures 1130, a molded layer 1150, and bumps 1160. For example, the molded layer 1150 and the molded layer 1500 of FIG. 5C may include Epoxy Molding Compound (EMC).

The redistribution structure 1110 may have a structure in which at least one redistribution insulating layer 1111 and at least one redistribution layer 1112 are alternately stacked. For example, the redistribution structure 1110 is a support substrate on which the semiconductor chip 100 is mounted, and may be a package substrate for interconnecting the pad 1121 of the semiconductor chip 100. Examples of the package substrate may include a printed circuit board (PCB), a ceramic substrate, a glass substrate, a tape interconnection substrate, and the like. The redistribution structure 110 may include redistribution insulating layers 1111, redistribution layers 1112, redistribution vias 1113, an upper solder mask layer 1115, and a lower solder mask layer 1116. In example embodiments, the number of redistribution insulating layers 1111 and redistribution layers 1112 forming the redistribution structure 1110 may vary. In some embodiments, the redistribution structure 1110 may be an interposer substrate, for example, an organic interposer. In some embodiments, the redistribution structure 1110 may be a module substrate, in which case the semiconductor chip 100 may be a semiconductor structure such as a semiconductor package.

The redistribution insulating layers 1111 include an insulating material and may include, for example, a thermosetting resin such as epoxy resin or a thermoplastic resin such as polyimide. For example, the redistribution insulating layers 1111 may include a photosensitive insulating material such as PID (Photo Imageable Dielectric) resin. Alternatively, the insulating layers 111 may include a resin mixed with an inorganic filler, for example, Ajinomoto Build-up Film (ABF). Alternatively, the redistribution insulating layers 1111 may include prepreg, flame retardant (FR-4), or bismaleimide triazine (BT). The redistribution insulating layers 1111 may include the same or different materials. The boundaries between the redistribution insulating layers 1111 may not be distinct depending on the materials and processes that make up each layer.

The redistribution layers 1112 and the redistribution vias 1113 may form an electrical path. The redistribution layers 1112 and the redistribution vias 1113 may interconnect the semiconductor chip 100 to an area outside the semiconductor chip 100, for example, to a fan-out area that does not overlap the semiconductor chip 100 in the Z-direction. Accordingly, the semiconductor package 1000c of this embodiment may be referred to as a fan-out semiconductor package. However, the form of the semiconductor package is not limited thereto, and in some embodiments, the semiconductor package 1000c may form a fan-in semiconductor package. The redistribution layers 1112 and redistribution vias 1113 may include a ground pattern, a power pattern, and a signal pattern. The redistribution layers 1112 may be disposed in a line shape on the x-y plane, and the redistribution vias 1113 may have a cylindrical shape with a side surface slanted so that the width is narrowed toward the bottom or top. The redistribution vias 1113 are illustrated as filled via structures whose interior is completely filled with a conductive material, but are not limited thereto. For example, the redistribution vias 1113 may have a conformal via shape in which a metal material is formed along the inner wall of the via hole.

The redistribution layers 1112 and the redistribution vias 1113 may include a conductive material, and for example, may include copper (Cu), aluminum (Al), silver (Ag), tin (Sn), gold (Au), nickel (Ni), lead (Pb), titanium (Ti), or alloys thereof. Depending on the width of the interconnection of the redistribution layers 1112 or the spacing between the interconnections (for example, 10 μm to 100 μm), the interconnection of the redistribution layers 1112 may be implemented as wiring on a printed circuit board. FIG. 8 illustrates a redistribution structure 1110, a Protruded Trace Substrate (PTS) having a structure, in which the uppermost and lowermost interconnection layers of the redistribution layers 1112 protrude upward and downward from the uppermost and lowermost insulating layers of the redistribution insulating layers 1111, but depending on the design, the redistribution structure 1110 may be an Embedded Trace Substrate (ETS).

The redistribution layers 1112 may include a plurality of lower pads 1112P3 exposed through the lower solder mask layer 1116. A plurality of lower pads 1112P3 may be disposed on the lowermost insulating layer among the redistribution insulating layers 1111, and the lower solder mask layer 1116 may be exposed downward through a plurality of upper and lower passages and be electrically connected to a plurality of bumps 1160. Each of the plurality of lower pads 1112P3 may have a circular or polygonal upper and lower surface. As the diameter of each of the plurality of bumps 1160 increases, the width of each of the plurality of lower pads 112P3 may also increase.

The upper and lower solder mask layers 1115 and 1116 may be solder resist layers that protect the redistribution layer 1112 from external physical and chemical damage. The upper and lower solder mask layers 1115 and 1116 include an insulating material and may include, for example, prepreg, ABF, FR-4, BT, or Photo Solder Resist (PSR).

Each of the electrical connection structures 1130 and bumps 1160 may include a low melting point (melting point lower than the melting point of pad 1121) metal, such as lead (Pb), bismuth (Bi), tin (Sn), alloys (Sn-Ag-Cu) containing tin (Sn), and the like, but is not limited thereto. Each of the electrical connection structures 1130 and bumps 1160 may have a land, ball, or pin shape and may be made of a single layer or multiple layers. For example, each of the electrical connection structures 1130 and bumps 1160 may be a solder ball. At a temperature higher than the melting point, each of the electrical connection structures 1130 and the bumps 1160 may be in a fluid state by a reflow process or a thermal compression bonding (TCB) process. Thereafter, as the temperature decreases, each of the electrical connection structures 1130 and bumps 1160 may be connected to and fixed to the pads of the redistribution layer 1112.

As set forth above, in a semiconductor package and a method of manufacturing a semiconductor package according to example embodiments, defects (for example, cracks, kinking, peeling, and the like) of semiconductor chips caused by wafer division may be efficiently prevented, or productivity (for example, yield, costs, time, and the like) of wafer division may be efficiently increased. For example, semiconductor packages and methods of manufacturing semiconductor packages may reduce heat affected zone due to wafer division, and thus, strength of semiconductor chips may be improved and productivity of a wafer division process related to the heat affected zone may be increased.

While example embodiments have been illustrated and described above, it will be apparent to those skilled in the art that modifications and variations could be made without departing from the scope of the present invention as defined by the appended claims.

1. A semiconductor device comprising:
a semiconductor chip including a substrate, an interconnection structure on a front surface of the substrate, and a pad layer on a front surface of the interconnection structure,
wherein, as viewed from a cross-section, a first side surface of the semiconductor chip from a point on a side surface of the substrate to an edge of a front surface of the semiconductor chip is oblique to, or more curved than, the front surface of the semiconductor chip, and is oblique to, or more curved than, a second side surface of the semiconductor chip from the point to an edge of a back surface of the semiconductor chip.

2. The semiconductor device of claim 1, wherein the side surface of the substrate has an angular shape at the point.

3. The semiconductor device of claim 2, wherein:
the first side surface of the semiconductor chip is flat-shaped from the point to the edge of the front surface of the semiconductor chip, and
the second side surface of the semiconductor chip is flat-shaped from the point to the edge of the back surface of the semiconductor chip.

4. The semiconductor device of claim 3, wherein roughness of the first side surface of the semiconductor chip is rougher than roughness of the second side surface of the semiconductor chip.

5. The semiconductor device of claim 3, wherein in a horizontal direction of the semiconductor chip, a maximum width component of the first side surface of the semiconductor chip is greater than 3 μm and less than 100 μm, and
in a vertical direction of the semiconductor chip, a maximum height component of the first side surface of the semiconductor chip is greater than 10 μm and less than 300 μm.

6. The semiconductor device of claim 1, wherein a maximum width component of the first side surface of the semiconductor chip in a horizontal direction of the semiconductor chip is greater than 0.1 times and less than 1 times a maximum height component of the first side surface of the semiconductor chip in a vertical direction of the semiconductor chip.

7. The semiconductor device of claim 1, further including a plurality of memory chips on a front surface of the pad layer so that at least portions of respective memory chips overlap each other in a vertical direction,
each of the plurality of memory chips includes a memory cell layer having memory cells,
among the plurality of memory chips, a memory chip closest to the pad layer further includes a bonding metal layer disposed between the memory cell layer and the semiconductor chip, and
a front surface of the semiconductor device is a front surface of a memory chip located furthest from the pad layer among the plurality of memory chips.

8. The semiconductor device of claim 1, further including a memory chip on a front surface of the pad layer,
wherein the memory chip includes,
a memory cell layer having memory cells; and
a bonding metal layer between the memory cell layer and the semiconductor chip, and
the front surface of the semiconductor device is the front surface of the memory chip.

9. The semiconductor device of claim 8, further comprising a connection pad on the memory chip,
wherein the memory cell layer includes a plate layer electrically connected to the connection pad, gate electrodes stacked on a lower surface of the plate layer and spaced apart from each other in a first direction, perpendicular to the lower surface of the plate layer, and electrically connected to the bonding metal layer, and vertical channel structures extending in the first direction while penetrating through the gate electrodes and electrically connected to the bonding metal layer.

10. The semiconductor device of claim 1, including a plurality of semiconductor chips connected to each other through direct bonding, and
for each semiconductor chip of the semiconductor chips, a first side surface from a point on a side surface of a substrate of the semiconductor chip to an edge of a front surface of the semiconductor chip is oblique to, or more curved than, a second side surface from the point on the side surface of the substrate of the semiconductor chip to an edge of a back surface of the semiconductor chip.

11. The semiconductor device of claim 1, wherein:
the interconnection structure includes an interconnection line and an interconnection insulating layer,
the pad layer includes a pad and a pad insulating layer, and
each of the interconnection insulating layer and the pad insulating layer includes at least one of SiO₂, SiN, SiCN, and tetraethyloxysilane (TEOS).

12. The semiconductor device of claim 11, wherein the first side surface of the semiconductor chip has a heat affected zone, and
the point is a bottommost point of the heat affected zone.

13. The semiconductor device of claim 12, wherein in at least a portion of the heat affected zone, at least one of SiO₂, SiN, SiCN and TEOS is mixed with a metallic material.

14. A semiconductor package comprising:
a semiconductor chip including a substrate, an interconnection structure disposed on a front surface of the substrate, and a pad layer disposed on a front surface of the interconnection structure,
wherein, as viewed from a cross-section, a first side surface of the semiconductor chip from a point on a side surface of the substrate to an edge of a front surface of the semiconductor chip has a heat affected zone,
wherein the point is a bottom of the heat affected zone.

15. The semiconductor package of claim 14, wherein, as viewed from the cross-section, a second side surface of the semiconductor chip from the point to an edge of a back surface of the semiconductor chip does is not a heat affected zone, and wherein roughness of the first side surface of the semiconductor chip is rougher than roughness of the second side surface of the semiconductor chip.

16. (canceled)

17. The semiconductor package of claim 14, wherein in at least a portion of the heat affected zone, an insulating material and a metallic material are mixed with each other.

18. The semiconductor package of claim 14, wherein a width of the heat affected zone increases from a point on the side surface of the substrate toward the edge of the front surface of the semiconductor chip, and wherein the heat affected zone runs continuously from the point to the edge of the front surface of the semiconductor chip.

19. (canceled)

20. The semiconductor package of claim 14, further including a plurality of memory chips disposed on a front surface of the pad layer so that at least portions of respective memory chips overlaps each other in a vertical direction,
each of the plurality of memory chips includes a memory cell layer having memory cells,
among the plurality of memory chips, a memory chip disposed closest to the pad layer further includes a bonding metal layer disposed between a memory cell layer and the semiconductor chip, and
the front surface of the semiconductor package is a front surface of a memory chip located furthest from the pad layer among the plurality of memory chips.

21. The semiconductor package of claim 14, further including:
a memory chip on a front surface of the pad layer; and
a connection pad on the memory chip,
wherein the memory chip includes,
a memory cell layer having memory cells; and
a bonding metal layer between the memory cell layer and the semiconductor chip,
wherein the front surface of the semiconductor package is a front surface of the memory chip, and wherein the memory cell layer includes a plate layer electrically connected to the connection pad, gate electrodes stacked on a lower surface of the plate layer and spaced apart from each other in a first direction, perpendicular to the lower surface of the plate layer, and electrically connected to the bonding metal layer, and vertical channel structures extending in the first direction while penetrating through the gate electrodes and electrically connected to the bonding metal layer.

22. (canceled)

23. The semiconductor package of claim 14, including a plurality of semiconductor chips connected to each other through direct bonding, and
for each semiconductor chip of the plurality of semiconductor chips, a first side surface from a point on a side surface of a substrate of the semiconductor chip to an edge of a front surface of the semiconductor chip is oblique to, or more curved than, a second side surface from a point on the side surface of the substrate of the semiconductor chip to an edge of a back surface of the semiconductor chip.

24-30. (canceled)
